(19) United States
(12) Patent Application Publication
(10) Pub. No.: US 2015/0365073 A1
(43) Pub. Date: Dec. 17, 2015

(54) APPARATUS, METHOD AND A COMPUTER PROGRAM FOR RESONANCE TUNING

(71) Applicant: NOKIA TECHNOLOGIES OY, Espoo (FI)

(72) Inventor: Juha HALLIVUORI, Tampere (FI)

(21) Appl. No.: 14/762,316

(22) PCT Filed: Jan. 22, 2013
(86) PCT No.: PCT/FI2013/050067

§ 371 Date: Jul. 21, 2015

(51) Int. Cl. H03J 1/00

(52) U.S. Cl. CPC H03J 1/0016

(57) ABSTRACT

There are disclosed various methods, apparatuses and computer program products for resonance tuning. In some embodiments an oscillator signal derived from a local oscillator (125) signal is received and a control signal (208) is generated by using the oscillator signal. The control signal is to be provided to a resonance tuning circuit (202) configured to be coupled to an antenna (102); and a signal level indication (228) on the basis of the resonance of the resonance tuning circuit is produced. The signal level indication (228) is compared with a reference signal (224); and on the basis of the comparison it is determined whether the resonance of the antenna effected by the generated control signal (208) fulfills a determined condition. In some embodiments there is provided an apparatus comprising a resonance tuning circuit (202) configured to be coupled to an antenna (102), a control element (204) comprising an input to receive an oscillator signal derived from a local oscillator (125) signal, the control element (204) configured to produce a control signal (208) for the resonance tuning circuit (202) by using the oscillator signal, a signal level detector (230) to generate a signal level indication (228) on the basis of the resonance of the resonance tuning circuit (202), a comparator (222) for comparing the signal level indication (228) with a reference signal (224), and the control element (204) further to determine on the basis of the comparison whether the resonance of the antenna effected by the generated control signal fulfills a determined condition.

### TECHNICAL FIELD

The present invention relates to an apparatus for adjusting a resonance of an antenna interface with respect to a defined frequency range. The invention further relates to a method and a computer program for adjusting a resonance of an antenna interface with respect to a defined frequency range.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

A modern radio telecommunication environment is very diverse with the use of numerous radio communication schemes, both standard and nonstandard. User devices may be equipped with capabilities to communicate through multiple different radio communication schemes, e.g. GSM, GPRS/EDGE, Bluetooth, WLAN, UMTS and its evolution versions HSDPA, LTE and LTE-A. Additionally, concepts like cognitive radio or software-defined radio (SDR) may be implemented in the user devices in the future.

Cognitive radio is a general concept to denote radio devices that are able to sense a radio environment and to select a radio communication scheme and radio communication parameters that may be the most suitable for the sensed radio environment.

In a mobile transceiver a front-end module (FEM) provides means to connect one or more antennas to one or more multiple system transceiver engines. Switches and filters may provide some frequency selectivity with connected wide/multiband antennas.

When more and more systems are to be added to the mobile devices the loss, size and/or cost penalty of current solutions may increase rapidly to the point when the current way may not be applicable.

### SUMMARY

Some embodiments utilize the use of local oscillator signals (transmitter and/or receiver). Accurate (phase locked) oscillator signal may carry information to set up a resonance frequency based antenna interface with good enough accuracy and speed. In some embodiments the idea is to feed to the antenna interface the local oscillator signal and sense/optimize the amplitude of that interface during a frequency/band switching initialization period. For that initialization timing, a state information may be provided to the apparatus when the tuning can be made without effecting the reception or transmission. With a bit counter or similar means, the resonance frequency of the interface may be changed by changing the component values affecting to the resonance frequency. For example a capacitance matrix, in which the capacitance value can be changed by activating/de-activating capacitances, can be used. In some other embodiments, a voltage controlled capacitor may be used instead or in addition to the capacitance matrix. The interface amplitude may be monitored and once the maximum for that particular oscillator signal is found, switch configuration to be used reception/transmission may be identified. A serial resonance may be detected in which a minimum voltage is searched. Other approach may detect maximum current, minimum current, maximum voltage etc.

Various aspects of examples of the invention are provided in the detailed description.

According to a first aspect, there is provided a method comprising: receiving an oscillator signal derived from a local oscillator signal; generating a control signal by using the oscillator signal to a resonance tuning circuit configured to be coupled to an antenna;

producing a signal level indication on the basis of the resonance of the resonance tuning circuit;
comparing the signal level indication with a reference signal; and
on the basis of the comparison determining whether the resonance of the antenna effected by the generated control signal fulfills a determined condition.

According to a second aspect, there is provided an apparatus comprising:

a resonance tuning circuit configured to be coupled to an antenna;
a control element comprising an input to receive an oscillator signal derived from a local oscillator signal, the control element configured to produce a control signal for the resonance tuning circuit by using the oscillator signal;
a signal level detector to generate a signal level indication on the basis of the resonance of the resonance tuning circuit;
a comparator for comparing the signal level indication with a reference signal; and
the control element further to determine on the basis of the comparison whether the resonance of the antenna effected by the generated control signal fulfills a determined condition.

According to a third aspect, there is provided an apparatus comprising at least one processor and at least one memory including computer program code, the at least one memory and the computer program code configured to, with the at least one processor, cause the apparatus to:
receive an oscillator signal derived from a local oscillator signal;
generate a control signal by using the oscillator signal to a resonance tuning circuit configured to be coupled to an antenna;
produce a signal level indication on the basis of the resonance of the resonance tuning circuit;
compare the signal level indication with a reference signal; and
on the basis of the comparison to determine whether the resonance of the antenna effected by the generated control signal fulfills a determined condition.

According to a fourth aspect, there is provided a computer program product embodied on a non-transitory computer readable medium, comprising computer program code configured to, when executed on at least one processor, cause an apparatus or a system to:
receive an oscillator signal derived from a local oscillator signal;
generate a control signal by using the oscillator signal to a resonance tuning circuit configured to be coupled to an antenna;
produce a signal level indication on the basis of the resonance of the resonance tuning circuit;
compare the signal level indication with a reference signal; and
on the basis of the comparison to determine whether the resonance of the antenna effected by the generated control signal fulfills a determined condition.

According to a fifth aspect, there is provided an apparatus comprising:
means for receiving an oscillator signal derived from a local oscillator signal;
means for generating a control signal by using the oscillator signal to a resonance tuning circuit configured to be coupled to an antenna ;
means for producing a signal level indication on the basis of the resonance of the resonance tuning circuit;
means for comparing the signal level indication with a reference signal; and
means for determining, on the basis of the comparison, whether the resonance of the antenna effected by the generated control signal fulfills a determined condition.

According to a sixth aspect, there is provided an apparatus comprising:
an oscillator signal derived from a local oscillator signal;
a control signal generated by using the oscillator signal to a resonance tuning circuit configured to be coupled to an antenna;
a signal level indication produced on the basis of the resonance of the resonance tuning circuit;
a comparator for comparing the signal level indication with a reference signal; and
a control element configured to determine on the basis of the comparison whether the resonance of the antenna effected by the generated control signal fulfills a determined condition.

By utilizing an existing local oscillator (LO) signal to tune the front end in a proposed manner the resonance of the antenna interface (front-end) may be set very close to the correct frequency. Component/temperature/usage based (hand-head) effects to the reception or transmission quality or other of these kinds of effects may be compensated according to the situation during the set up state. A control interface from a controlling element to the front-end may be unified between every possible combination of bands and systems allowing more robust designs with general components. A proposed solution may be unified between every possible combination of bands and systems, may require less external controlling and may allow a robust design.

### BRIEF DESCRIPTION OF THE DRAWINGS

For a more complete understanding of example embodiments of the present invention, reference is now made to the following descriptions taken in connection with the accompanying drawings in which:

FIG. 1 shows a block diagram of an apparatus according to an example embodiment;

FIG. 2 shows an apparatus according to an example embodiment;

FIG. 3 shows an example of an arrangement for wireless communication comprising a plurality of apparatuses, networks and network elements;

FIG. 4a shows a block diagram of RF and IF elements of a transceiver according to an example embodiment;

FIG. 4b shows a block diagram of a resonance tuning apparatus according to an example embodiment;

FIG. 5a illustrates an example of amplitude-frequency relationship of a resonance circuit with reference to a tuning capacitance value of the front end of an example embodiment;

FIG. 5b illustrates a smaller detail of the example of amplitude-frequency relationship of a resonance circuit of FIG. 5a;

FIG. 6 shows a high level flow chart of an embodiment of a method of adjusting the input impedance of the front end;

FIG. 7 illustrates an example of a front end module (FEM) of an apparatus; and

FIGS. 8a-8c illustrate examples of some blocks of a tuner.

### DETAILED DESCRIPTION OF SOME EXAMPLE EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

One solution to address the challenges caused by an increased number of systems possibly added to a mobile device may be to use a tunable antenna to a front-end interface but this may mean that the control logic size, amount of controls as well as component variation issues might become more meaningful than the front end design itself. Also an engine to front-end control interface may be fairly slow and may only support well fixed setups without proper feedback and monitoring.

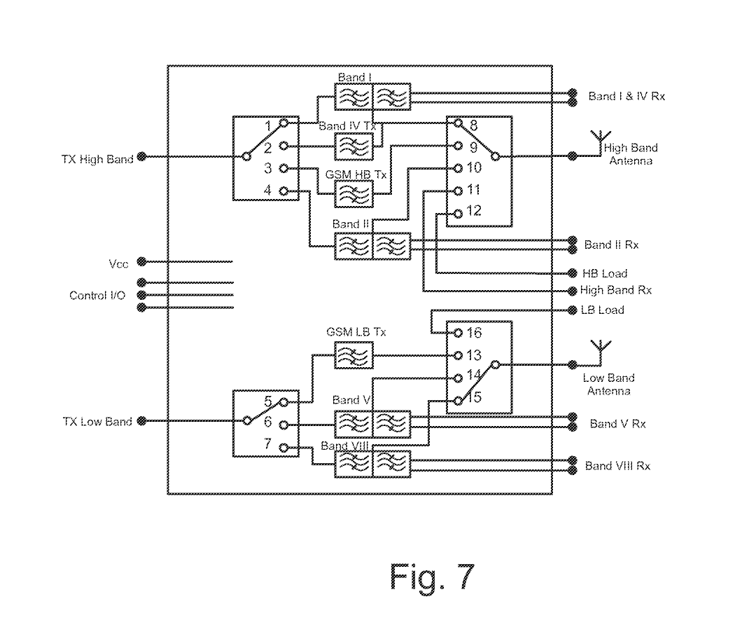

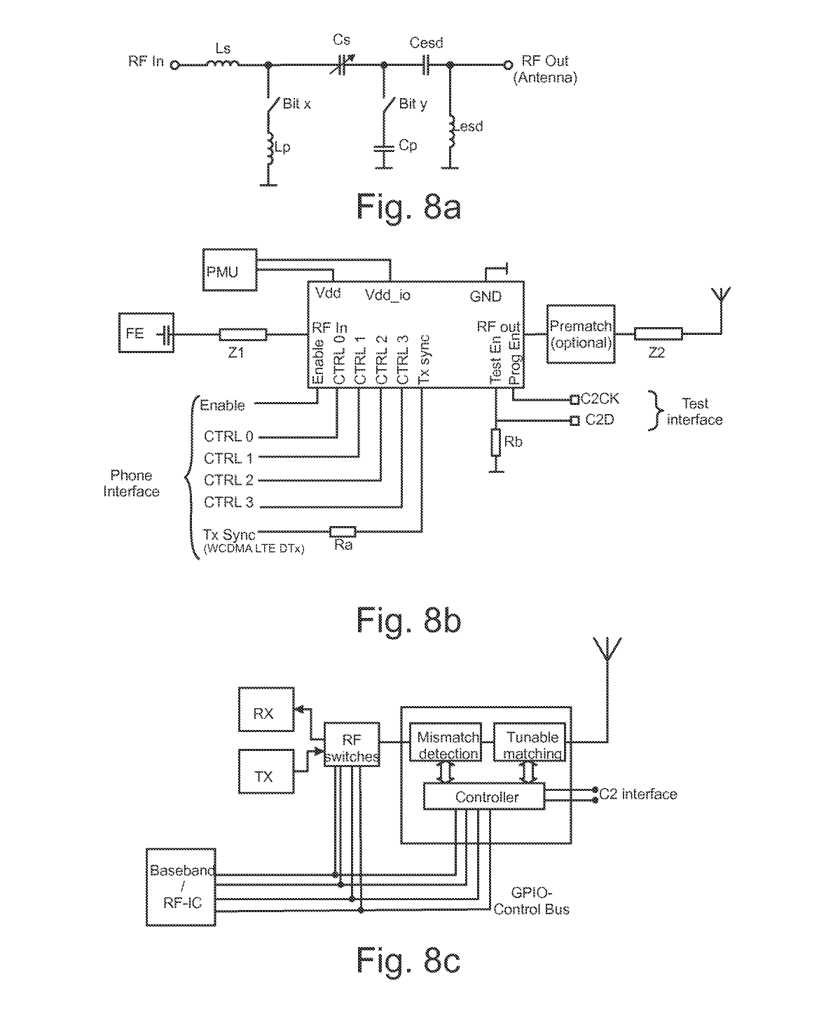

Currently band selection using one antenna may be made with digitally controlled switches which define the filters and “pipes” to be used. That is fixed approach and without fine tuning or component variation compensation. This may not be a problem with few frequencies and system bands but increasing amount of bands/systems may cause this approach to fail. The antenna matching fine tuning and component variation compensation might be on the other hand handled with separate circuitry and logic. These front end tuners may suffer from complexity (cost and size issues) as well from fairly moderate performance. FIG. 7 illustrates an example of a front-end module (FEM) and FIGS. 8a-8c illustrate examples of some blocks of a tuner approach. Predefined settings may be used first to tune the reception (RX) frequency in a large scale in this tuner since the front-end module is partly integrated in as preconfigured switched states. Capacitance Cs may then be used in the tuning itself. In some examples the impedance fine tuning speed of the tuner may be appr. 70 μs and that does not take into account the band selection time.

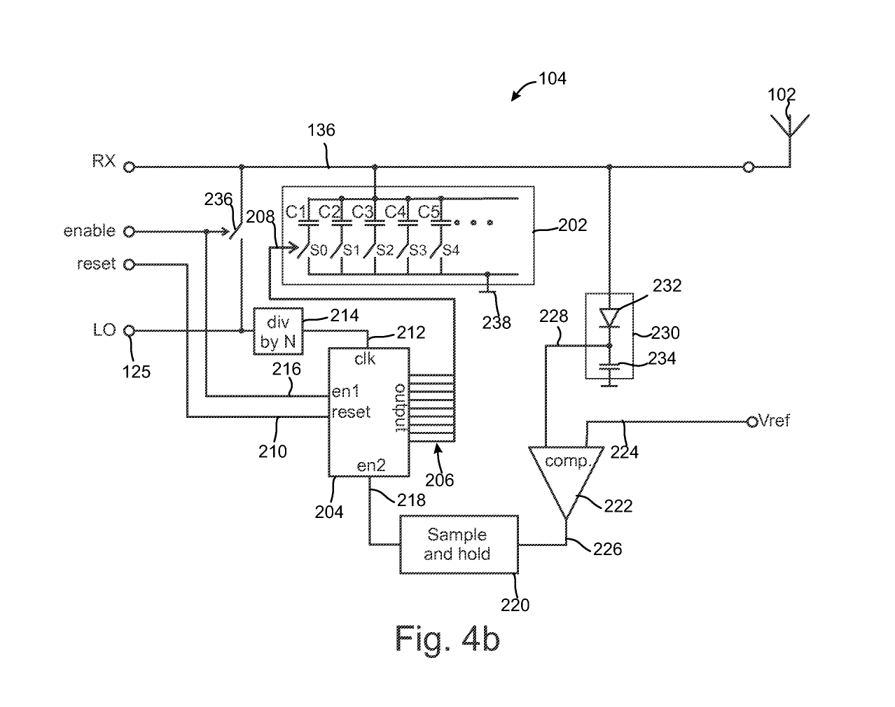

FIG. 4a shows a block diagram of radio frequency (RF) and intermediate frequency (IF) elements of an apparatus 100 according to an example embodiment. In this non-limiting example embodiment the apparatus 100 comprises a transmitter and a receiver. This kind of apparatus may also be called as a transceiver. However, the resonance tuning element may also be embodied in devices comprising only a receiver.

The receiver converts a received radio signal first to the intermediate frequency and then to a baseband. In some other embodiments the intermediate frequency part is not needed wherein such receivers, which may also be called as direct-conversion receivers, convert a received radio signal directly to the baseband.

In the example embodiment of FIG. 4a, the apparatus comprises an antenna 102 for receiving RF signals. The antenna 102 is connected with a resonance tuning element 104. The connection between the antenna 102 and the resonance tuning element 104 may be called as an interface for an antenna, for example. The connection may be implemented by using a balun or other element which can be used to create a differential RF signal for the resonance tuning element 104. The connection may also be a single ended and without any additional components or some combination. The resonance tuning element 104 may be used to tune the resonance with the impedance of the antenna and the impedance of the front end of the receiver at the frequency range. The resonance tuning element 104 is also provided with one or more timing signals 125 TP_P1, which may be formed by a timing element 124 on the basis of a local oscillator signal 142 from a local oscillator 122. In some embodiments the timing element 124 may not be needed wherein the local oscillator signal may be inputted directly to the resonance tuning element 104, for proper operation some other than LO based enable/reset signals might be needed. In this embodiment the resonance tuning element 104 is also connected to a radio frequency switch (RF switch) 105 which may be used to switch the resonance tuning element 104 with the receiver section, when receiving signals via the antenna 102, or to the transmitter section, when transmitting signals via the antenna 102. In some embodiments there may be separate antennas for the receiver and the transmitter wherein the RF switch 105 may not be needed or the component 105 may be a component performing a duplexing between the TX and RX frequencies in an FDD (Frequency Division Duplex) mode.

The RF switch 105 is connected to a first amplifier 106. The first amplifier 106 may be a low-noise amplifier (LNA) or another kind of amplifier suitable for amplifying RF signals. The amplified RF signals may then be filtered by a first bandpass filter 108 to eliminate or attenuate signals which are outside the desired frequency range of the RF signals. The RF signals may then be converted to intermediate signals (IF) or directly to bandbass signals by mixing the RF signals with other signals LO_0, LO_90, LO_180, LO_270 from the same local oscillator 122 or from another local oscillator. The bandbass signals may then be amplified by a second amplifier 112, low pass filtered by a lowpass filter 114 and again amplified by the third amplifier 116. The bandpass signals, which may be regarded as analogue signals at the output of the third amplifier, may be converted to digital representations (e.g. samples) by an analogue-to-digital converter 118 so that the signals may be digitally processed in further processing steps. The further processing steps are not described in more detail here but may comprise control signal processing such as call control processing, audio signal processing, video signal processing, etc.

In some embodiments the timing signal(s) TP_P1 may be derived from more than one local oscillator LO signal. For example a multicarrier reception may utilize this scenario.

It should be noted here that in some embodiments the baseband signals may include two quadrature phase signals I (In-phase) and Q (Quadrature phase), wherein the baseband section 112-118 may include separate signal processing paths for these two signals. In that case the local oscillator 122 would provide four local oscillator signals LO_0, LO_90, LO_180, LO_270 having different phase shifts (i.e. 0 degrees, 90 degrees, 180 degrees and 270 degrees).

FIG. 4a also depicts a part of a transmitter of the apparatus. A signal to be transmitted is input to the mixer 130 of the transmitter in which the signal is mixed with the local oscillator signal from the local oscillator 122. The mixing result is amplified by an amplifier 132 and band bass filtered by the band bass filter 134 so that the signals at the correct transmitting frequency may be connected via the RF switch 105 to the resonance tuning element 104 and to the transmitting antenna 136 or, in some embodiments, to a separate transmitting antenna (not shown).

FIG. 4b depicts a simplified block diagram of the resonance tuning element 104 according to an example embodiment. In this embodiment the resonance may be tuned by changing the capacitance of the tuning circuitry 202. The capacitance may be changed by connecting or disconnecting capacitors C1, C2, . . . of a capacitance matrix of the tuning circuitry 202 e.g. by using switches S0, S1, . . . . In FIG. 4b only five capacitors C1, C2, . . . , C5 and five switches S0, S1, . . . , S4 are shown but in practical embodiments the number of capacitors and switches may differ from five, e.g. there may be more than five or less than five capacitors and switches.

The capacitance values of the capacitance matrix may be selected in such a way that an appropriate tuning range may be achieved. For example, the capacitance values of different capacitances may be powers of two or another ratio. In some embodiments the smallest capacitance value (e.g. the capacitance of the first capacitor C1) may be indicated with C, wherein the second capacitor C2 may have the value of 2C, the third capacitor C3 may have the value of 2²C, the fourth capacitor C4 may have the value of 2³C, the fifth capacitor C5 may have the value of 2⁴C, etc.

In the embodiment of FIG. 4b the resonance tuning element 104 also comprises a switch controller 204 which may be used to generate a control signal at the output 206 of the switch controller 204. The output 206 of the switch controller 204 may then be used as a control signal 208 to control the state of the individual switches S0-S4. For example, the output may comprise as many signal lines as there are switches in the tuning circuitry 202. Hence, the control signal may comprise binary information for each switch which controls whether the switch is open or closed. The binary information may be implemented as two different voltage levels. In some embodiments a lower voltage (e.g. about 0 V) may represent a binary 0 state and a higher voltage (e.g. about 1.2 V, 3 V or 5 V) may represent a binary 1 state, or vice versa. The binary 0 state provided to a switch may cause the switch to be open (the corresponding capacitor of the capacitance matrix is disconnected) and, respectively, the binary 1 state provided to a switch may cause the switch to be closed (the corresponding capacitor of the capacitance matrix is connected).

In some embodiments the signals at the output 206 of the switch controller 204 are the same signals than the control signal 208 to be provided to the switches S0-S4. In some other embodiments there may be buffers, level shifters and/or some other circuitry to e.g. adapt the voltage levels and/or currents provided by the output 206 to enable correct operation of the switches S0-S4.

In the embodiment of FIG. 4b, the resonance tuning element 104 may have 2^{m} different capacitance values for tuning the resonance of the front end when using m capacitors in the capacitance matrix.

The switch controller 204 may have several control inputs. A reset input 210 may be used to reset the output of the switch controller 204 into a default value, e.g. to 0, wherein all the switches may be open and no capacitors of the capacitance matrix are connected to the RX line 210. A clock input 212 may be used to provide an oscillator signal to the switch controller 204. The oscillator signal may be based on the local oscillator signal 125 divided by a dividend N. In some example embodiments the dividend may be 10, wherein the frequency of the clock signal at the clock input 212 is one tenth of the frequency of the local oscillator signal. However, the dividend may be different from 10. The clock signal for the switch controller 204 may be generated e.g. by a divider element 214 in which a predetermined dividend value N may be used or the dividend may be programmable wherein it may be possible to change the value of the dividend in different embodiments/situations.

The switch controller 204 may also have a first enable input and a second enable input. They may be used to start and stop the adjustment of the capacitance value of the capacitance matrix as will be described later in this application.

The resonance tuning element 104 may further comprise a signal level detector 230 to produce a measurement signal indicative of the resonance of the antenna circuit. The measurement signal may be formed on the basis of the RF signal on the antenna line 136 e.g. by a rectifier 232 (such as a diode) and a capacitor 234. The rectifier 232 and the capacitor 234 form a DC voltage at line 228 which is proportional to the RF signal level at the line 136. The DC voltage is input to a comparator 222, which is also provided with a reference voltage Vref at another input 224 of the comparator 222. The comparator 222 produces an output signal 226 on the basis of the comparison of the voltage levels at the inputs of the comparator 222.

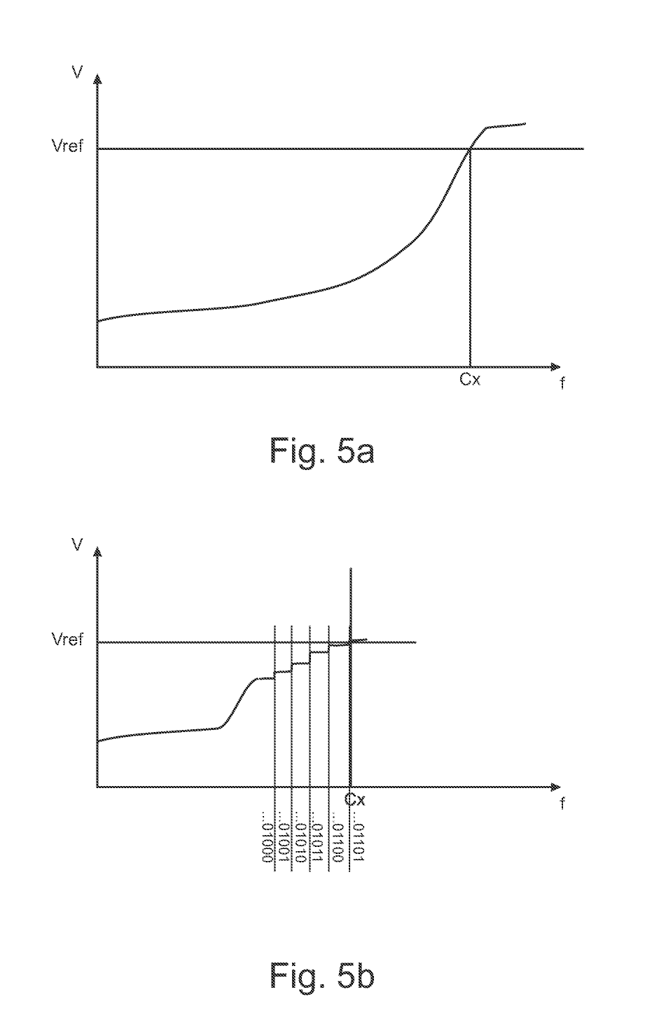

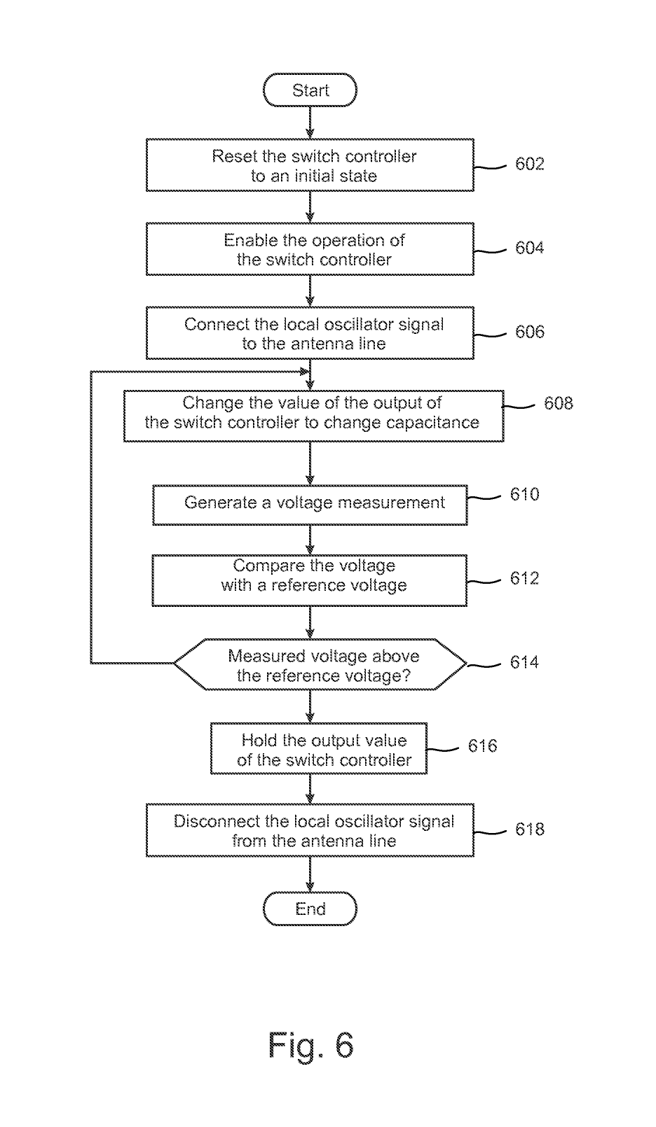

In the following the operation of the resonance tuning element 104 will be described in more detail with reference to the flow diagram of FIG. 5 and the example circuitry of FIG. 4b. It is assumed that the control logic 120 (or another control element) decides to tune the resonance of the antenna circuit. Hence, the control logic 120 may generate a reset signal at the reset line 210 (block 602 in FIG. 6). The signal sets the switch controller 204 to an initial state, for example to a state in which all the outputs are at the low level. This causes that all the switches are open and none of the capacitors of the capacitance matrix are connected between the antenna line 136 and the ground level 238. Ground level 238 in a differential connection may be the second input signal line. The control logic 120 may then set the enable signal at line 216 to a state which closes the switch 236 and enables the switch controller 120 to start operation (604). Closure of the switch 236 connects the local oscillator signal to the antenna line 136 (block 606). During the operation of the switch controller 120 the clock signal causes the switch controller to change values of the output 206 (block 608). In other words, the switch controller 204 operates as a counter for counting pulses at the clock input 212. For example, after a first pulse a first output line changes to a high level and the other output lines remain at the low level. After the next pulse the first output line changes back to the low level and a second output line changes state from the low level to the high level. Therefore, the values of the output lines represent the counted value.

The tuning circuitry and the antenna form a resonance circuit. By changing the capacitance of the tuning circuit the resonance may be changed which may cause that the signal level at the antenna line 136 may also change. The signal level is detected by the signal level detector 230 which produces a voltage 228 proportional to the signal level (block 610). The voltage 228 is input to the comparator 222 which compare the voltage with the reference voltage Vref (blocks 612, 614). When the voltage 228 from the signal level detector 230 is below the reference voltage Vref, the output of the comparator 222 is at a first state, e.g. at a low level. Hence, the output 218 of the sample and hold element 220 does not change. In a situation in which the voltage 228 from the signal level detector 230 rises above the reference voltage Vref, the output of the comparator 222 changes to a second state, e.g. to a high level. Hence, the output 218 of the sample and hold element 220 also changes and sets the second enable input to a state in which the switch controller 204 stops counting pulses at the clock input 212 and the output of the switch controller 204 remains in the state in which it was before disabling the counting by the state change at the second enable input 218 (block 616). In this situation the capacitance value of the tuning element 202 may be assumed to produce a resonance at the wanted frequency and the tuning may be stopped.

The switch 236 may then be opened (block 618) and the apparatus can begin to receive/transmit.

The switch controller 204 may keep the output at the state it remained when the counting was disabled until a next tuning operation is initiated. The tuning may be performed e.g. when the apparatus 100 changes to receive and/or transmit at a different frequency range and/or at predetermined intervals. The frequency range may be changed e.g. when the apparatus changes to use another communication network. The tuning may also be performed when the apparatus does not change the communication network but begins to use a communication channel of the same communication system which is distant (in frequency) from a previously used communication channel. This may happen e.g. when a mobile communication device performs handover.

The need for the tuning may be indicated e.g. by a processor of the apparatus 50 or by some other means.

FIG. 5a illustrates an example of amplitude-frequency relationship of a resonance circuit with reference to a tuning capacitance value of the front end of an example embodiment and FIG. 5b illustrates a smaller detail of the example of amplitude-frequency relationship of a resonance circuit of FIG. 5a. In FIGS. 5a and 5b the dotted horizontal line illustrates the reference voltage which may be used by the comparator 222 as a threshold value. The vertical dotted line illustrates the situation in which the voltage at line 228 has achieved the reference voltage value 224 wherein the comparator 222 may generate a signal to indicate that good enough resonance of the antenna circuit have been achieved and the tuning may be stopped. The notation Cx is used to indicate the corresponding capacitance value of the tuning circuitry 202. FIG. 5b illustrates as an example how the resonance of the antenna circuit might behave as a response to changes of the capacitance value of the tuning circuitry 202. The binary numbers 01000, 01001, . . . , 01101 below the frequency axes in FIG. 5b illustrate possible control values provided by the switch controller 204 to control the state of the individual switches S0-S4. Only five least significant bits of the control values are shown but it is obvious that the number of bits may also be more than five or less than five, depending on the number of switches S0-S4. From FIG. 5b it can be seen that the resonance may vary when the control value changes. In the non-limiting example of FIG. 5b the control value “. . . 01101” produces such a capacitance to the capacitance matrix which induces a voltage at the line 228 which is above the threshold voltage. Hence, a good enough resonance value may have been found and the output value of the switch controller 204 may be “freezed” i.e. the output value of the switch controller 204 may remain the same until the next tuning operation shall be performed.

In the above example it was assumed that the switch controller counted from 0 to a maximum value in an ascending order (e.g. 00000, 00001, 00010, 00011, 00100, 00101, . . . ). In some other embodiments the values of the output lines of the switch controller 104 may change in a different way. For example, a so called Grey code based principle may be used meaning that only one output line changes its state at a time (e.g. 00000, 00001, 00011, 00010, 00110, 00100, . . . ).

In the above described operation a capacitance value which produced a voltage above a threshold (Vref) at the antenna line 136 was an indication that good enough resonance has been achieved. In some other embodiments the tuning may be based on finding a maximum value for the voltage. This may need another kind of logic so that the tuning may include examining whether a certain capacitance value produces a maximum voltage value and whether the maximum voltage value is a so called global maximum value, not only a local maximum value.

In some embodiments the comparator may be replaced with analogue-to-digital converters and the sample and hold element may be replaced with a determination logic which examines whether the voltage is above a threshold or whether a global maximum has been found.

As a conclusion, there is provided a tuning circuitry including an inductive antenna connected to the capacitance matrix which may be implemented e.g. in an integrated circuit (IC) with fairly large tuning ratio. That matrix of switchable capacitances is connected to the counter 204 which changes the state in a way that a one-step change in it increases/decreases the interface capacitance by a small amount. An amplitude sensing circuit (rectifier) monitors the amplitude (voltage) e.g. until a certain pre-defined level or until the point when the amplitude starts to decrease. At that point the switch configuration is frozen, at that point the local oscillator signal is disconnected from the interface and normal reception/transmission can start. Tuning might need to be time synchronized with the other parts of the apparatus for prober operation.

If very large tuning range and small tuning time to settle the interface is needed, the settling time may be reduced by distributing the overall structure to couple of parallel or coarse/fine-tuning sections, in which the LO can be used in coarse frequency area selection first and after that for finer tuning.

Many embodiments of the present invention may be implemented in software defined radios in which the tuning of the front end is at least partially performed by software.

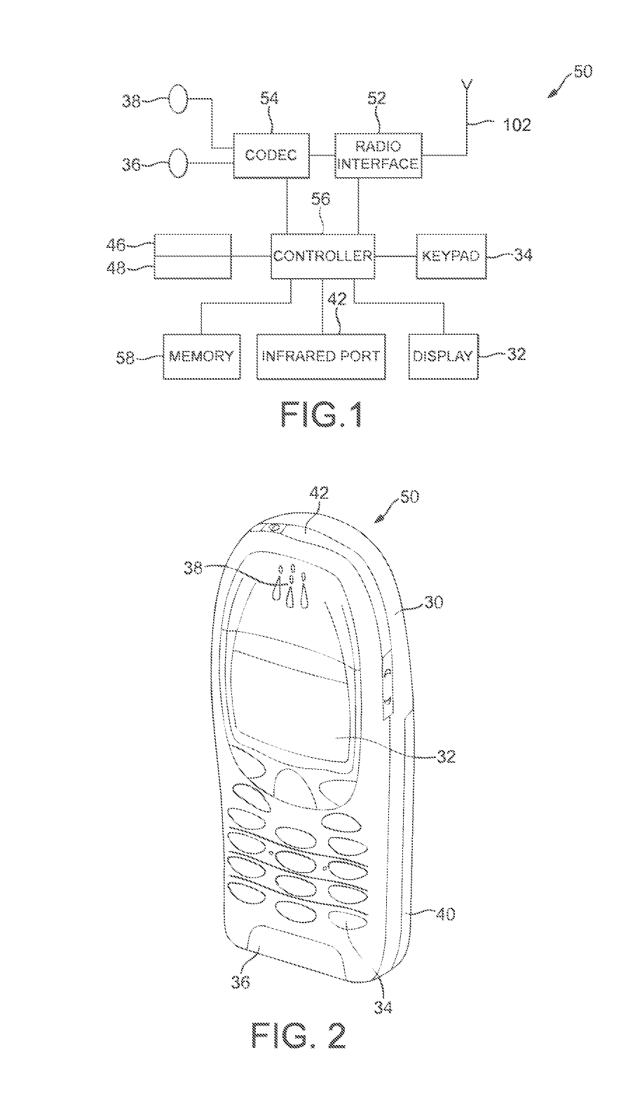

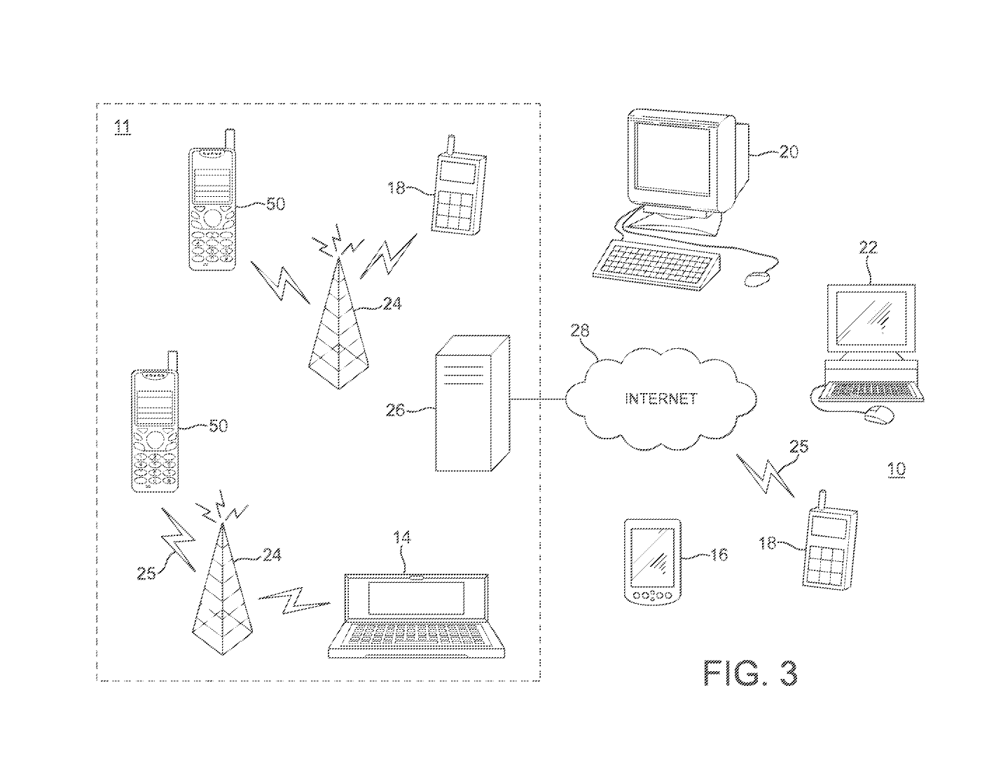

The following describes in further detail suitable apparatus and possible mechanisms for implementing the embodiments of the invention. In this regard reference is first made to FIG. 1 which shows a schematic block diagram of an exemplary apparatus or electronic device 50 depicted in FIG. 2, which may incorporate a receiver front end according to an embodiment of the invention.

The electronic device 50 may for example be a mobile terminal or user equipment of a wireless communication system. However, it would be appreciated that embodiments of the invention may be implemented within any electronic device or apparatus which may require reception of radio frequency signals.

The apparatus 50 may comprise a housing 30 for incorporating and protecting the device. The apparatus 50 further may comprise a display 32 in the form of a liquid crystal display. In other embodiments of the invention the display may be any suitable display technology suitable to display an image or video. The apparatus 50 may further comprise a keypad 34. In other embodiments of the invention any suitable data or user interface mechanism may be employed. For example the user interface may be implemented as a virtual keyboard or data entry system as part of a touch-sensitive display. The apparatus may comprise a microphone 36 or any suitable audio input which may be a digital or analogue signal input. The apparatus 50 may further comprise an audio output device which in embodiments of the invention may be any one of: an earpiece 38, speaker, or an analogue audio or digital audio output connection. The apparatus 50 may also comprise a battery 40 (or in other embodiments of the invention the device may be powered by any suitable mobile energy device such as solar cell, fuel cell or clockwork generator). The apparatus may further comprise an infrared port 42 for short range line of sight communication to other devices. In other embodiments the apparatus 50 may further comprise any suitable short range communication solution such as for example a Bluetooth wireless connection or a USB/firewire wired connection.

The apparatus 50 may comprise a controller 56 or processor for controlling the apparatus 50. The controller 56 may be connected to memory 58 which in embodiments of the invention may store both data and/or may also store instructions for implementation on the controller 56. The controller 56 may further be connected to codec circuitry 54 suitable for carrying out coding and decoding of audio and/or video data or assisting in coding and decoding carried out by the controller 56.

The apparatus 50 may further comprise a card reader 48 and a smart card 46, for example a UICC and UICC reader for providing user information and being suitable for providing authentication information for authentication and authorization of the user at a network.

The apparatus 50 may comprise radio interface circuitry 52 connected to the controller and suitable for generating wireless communication signals for example for communication with a cellular communications network, a wireless communications system or a wireless local area network. The apparatus 50 may further comprise an antenna 102 connected to the radio interface circuitry 52 for transmitting radio frequency signals generated at the radio interface circuitry 52 to other apparatus(es) and for receiving radio frequency signals from other apparatus(es).

In some embodiments of the invention, the apparatus 50 comprises a camera capable of recording or detecting imaging.

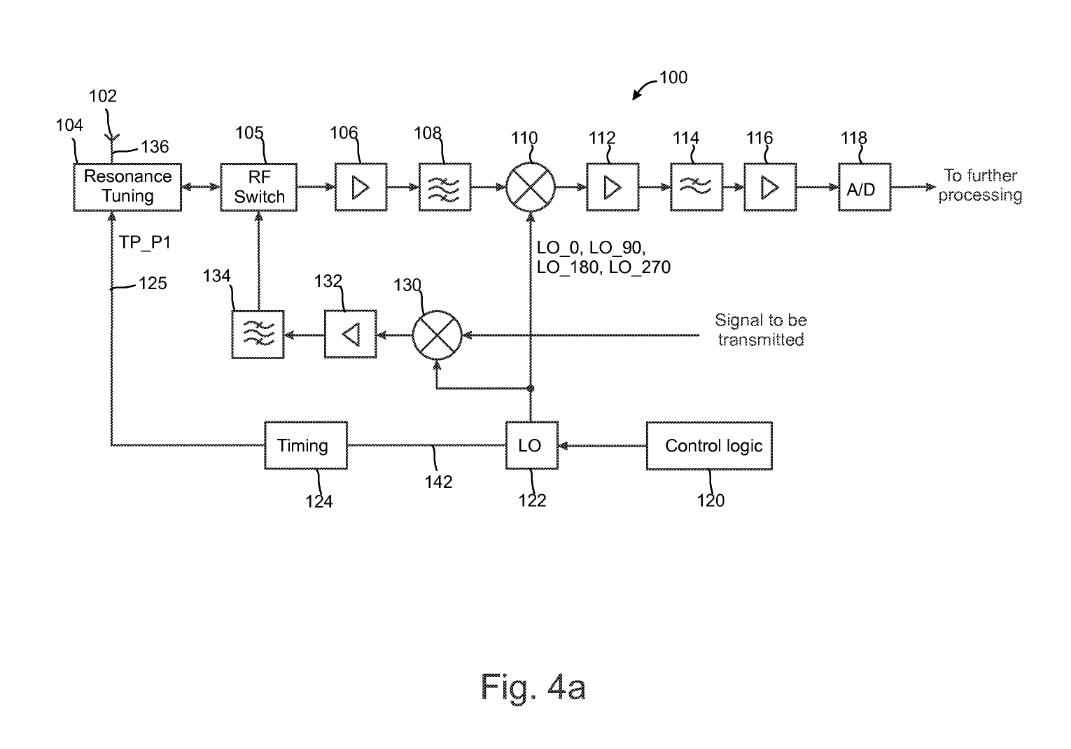

With respect to FIG. 3, an example of a system within which embodiments of the present invention can be utilized is shown. The system 10 comprises multiple communication devices which can communicate through one or more networks. The system 10 may comprise any combination of wired and/or wireless networks including, but not limited to a wireless cellular telephone network (such as a GSM, UMTS, CDMA network etc.), a wireless local area network (WLAN) such as defined by any of the IEEE 802.x standards, a Bluetooth personal area network, an Ethernet local area network, a token ring local area network, a wide area network, and the Internet.

The system 10 may include both wired and wireless communication devices or apparatus 50 suitable for implementing embodiments of the invention.

For example, the system shown in FIG. 3 shows a mobile telephone network 11 and a representation of the internet 28. Connectivity to the internet 28 may include, but is not limited to, long range wireless connections, short range wireless connections, and various wired connections including, but not limited to, telephone lines, cable lines, power lines, and similar communication pathways.

The example communication devices shown in the system 10 may include, but are not limited to, an electronic device or apparatus 50, a combination of a personal digital assistant (PDA) and a mobile telephone 14, a PDA 16, an integrated messaging device (IMD) 18, a desktop computer 20, a notebook computer 22. The apparatus 50 may be stationary or mobile when carried by an individual who is moving. The apparatus 50 may also be located in a mode of transport including, but not limited to, a car, a truck, a taxi, a bus, a train, a boat, an airplane, a bicycle, a motorcycle or any similar suitable mode of transport.

Some or further apparatus may send and receive calls and messages and communicate with service providers through a wireless connection 25 to a base station 24. The base station 24 may be connected to a network server 26 that allows communication between the mobile telephone network 11 and the internet 28. The system may include additional communication devices and communication devices of various types.

The communication devices may communicate using various transmission technologies including, but not limited to, code division multiple access (CDMA), global systems for mobile communications (GSM), universal mobile telecommunications system (UMTS), time divisional multiple access (TDMA), frequency division multiple access (FDMA), transmission control protocol-internet protocol (TCP-IP), short messaging service (SMS), multimedia messaging service (MMS), email, instant messaging service (IMS), Bluetooth, IEEE 802.11 and any similar wireless communication technology. A communications device involved in implementing various embodiments of the present invention may communicate using various media including, but not limited to, radio, infrared, laser, cable connections, and any suitable connection.

Although the above examples describe embodiments of the invention operating within a transceiver within an electronic device, it would be appreciated that the invention as described below may be implemented as part of any apparatus comprising a receiver and/or a transmitter. Thus, for example, embodiments of the invention may be implemented in a wireless communication device.

Thus, user equipment may comprise a transceiver such as those described in embodiments of the invention above. It shall be appreciated that the term user equipment is intended to cover any suitable type of wireless communication device, such as mobile telephones, portable data processing devices or portable web browsers.

Furthermore elements of a public land mobile network (PLMN) may also comprise transceivers as described above.

In general, the various embodiments of the invention may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The embodiments of this invention may be implemented by computer software executable by a data processor of the mobile device, such as in the processor entity, or by hardware, or by a combination of software and hardware. Further in this regard it should be noted that any blocks of the logic flow as in the Figures may represent program steps, or interconnected logic circuits, blocks and functions, or a combination of program steps and logic circuits, blocks and functions. The software may be stored on such physical media as memory chips, or memory blocks implemented within the processor, magnetic media such as hard disk or floppy disks, and optical media such as for example DVD and the data variants thereof, CD.

The memory may be of any type suitable to the local technical environment and may be implemented using any suitable data storage technology, such as semiconductor based memory devices, magnetic memory devices and systems, optical memory devices and systems, fixed memory and removable memory. The data processors may be of any type suitable to the local technical environment, and may include one or more of general purpose computers, special purpose computers, microprocessors, digital signal processors (DSPs) and processors based on multi core processor architecture, as non limiting examples.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention.

In the following some examples will be provided.

According to a first example, there is provided a method comprising:
receiving an oscillator signal derived from a local oscillator signal;
generating by using the oscillator signal a control signal to a resonance tuning circuit configured to be coupled to an antenna;
producing a signal level indication on the basis of the resonance of the resonance tuning circuit;
comparing the signal level indication with a reference signal;
on the basis of the comparison determining whether the resonance of the antenna effected by the generated control signal fulfills a determined condition.

In some embodiments the method further comprises:
if the determination indicates that the resonance of the antenna does not fulfill the determined condition, generating a different value for the control signal and repeating the producing and comparing steps.

In some embodiments producing a signal level indication comprises:
generating a voltage by the antenna.

In some embodiments comparing the signal level indication comprises:
using a reference voltage as the reference signal; and
comparing the generated voltage to the reference voltage.

In some embodiments the determining comprises:
determining that the resonance of the antenna fulfills the determined condition if the comparison indicates that the generated voltage is higher than or equal to the reference voltage.

In some embodiments the method comprises:
using a capacitance matrix as the resonance tuning circuit.

In some embodiments the method comprises:
using the control signal to connect or disconnect capacitors of the capacitance matrix to the antenna.

In some embodiments the method comprises:
using a binary signal as the control signal.

In some embodiments of the method the determined condition includes at least one of the following:
a threshold voltage;
a maximum voltage.

According to a second example there is provided an apparatus comprising:
a resonance tuning circuit configured to be coupled to an antenna;
a control element comprising an input to receive an oscillator signal derived from a local oscillator signal, the control element configured to produce a control signal for the resonance tuning circuit by using the oscillator signal;
a signal level detector to generate a signal level indication on the basis of the resonance of the resonance tuning circuit;
a comparator for comparing the signal level indication with a reference signal; and
a control element to determine on the basis of the comparison whether the resonance of the antenna effected by the generated control signal fulfills a determined condition.

In some embodiments the apparatus is adapted to change the value for the control signal, if the determination indicates that the resonance of the antenna does not fulfill the determined condition.

In some embodiments the signal level detector comprises a voltage generating element.

In some embodiments the apparatus comprises a reference voltage adapted to be used as the reference signal, wherein the comparator is configured to compare the generated voltage with the reference voltage.

In some embodiments the resonance tuning circuit comprises a capacitance matrix.

In some embodiments the apparatus comprises one or more switches to connect or disconnect capacitors of the capacitance matrix to the antenna by using the control signal.

In some embodiments the control signal is a binary signal.

In some embodiments of the apparatus the determined condition includes at least one of the following:
a threshold voltage;
a maximum voltage.

In some embodiments the apparatus comprises the antenna.

According to a third example, there is provided an apparatus comprising at least one processor and at least one memory including computer program code, the at least one memory and the computer program code configured to, with the at least one processor, cause the apparatus to:
receive an oscillator signal derived from a local oscillator signal;
generate a control signal by using the oscillator signal to a resonance tuning circuit configured to be coupled to an antenna;
produce a signal level indication on the basis of the resonance of the resonance tuning circuit;
compare the signal level indication with a reference signal; and
on the basis of the comparison to determine whether the resonance of the antenna effected by the generated control signal fulfills a determined condition.

In some embodiments of the apparatus said at least one memory stored with code thereon, which when executed by said at least one processor, causes the apparatus to perform at least the following:
generate a different value for the control signal and repeat the producing and comparing steps, if the determination indicates that the resonance of the antenna does not fulfill the determined condition.

In some embodiments of the apparatus said at least one memory stored with code thereon, which when executed by said at least one processor, causes the apparatus to perform at least the following:
generate a voltage by the antenna to represent the signal level indication.

In some embodiments of the apparatus said at least one memory stored with code thereon, which when executed by said at least one processor, causes the apparatus to perform at least the following:
use a reference voltage as the reference signal; and
compare the generated voltage to the reference voltage.

In some embodiments of the apparatus said at least one memory stored with code thereon, which when executed by said at least one processor, causes the apparatus to perform at least the following:
determine that the resonance of the antenna fulfills the determined condition if the comparison indicates that the generated voltage is higher than or equal to the reference voltage.

In some embodiments of the apparatus said at least one memory stored with code thereon, which when executed by said at least one processor, causes the apparatus to perform at least the following:
use a binary signal as the control signal.

In some embodiments of the apparatus the determined condition includes at least one of the following:
a threshold voltage;
a maximum voltage.

According to a fourth example, there is provided a computer program product embodied on a non-transitory computer readable medium, comprising computer program code configured to, when executed on at least one processor, cause an apparatus or a system to:
receive an oscillator signal derived from a local oscillator signal;
generate a control signal by using the oscillator signal to a resonance tuning circuit configured to be coupled to an antenna;
produce a signal level indication on the basis of the resonance of the resonance tuning circuit;
compare the signal level indication with a reference signal; and
on the basis of the comparison to determine whether the resonance of the antenna effected by the generated control signal fulfills a determined condition.

In some embodiments the computer program product comprises computer program code configured to, when executed by said at least one processor, causes the apparatus or the system to perform at least the following:
generate a different value for the control signal and repeat the producing and comparing steps, if the determination indicates that the resonance of the antenna does not fulfill the determined condition.

In some embodiments the computer program product comprises computer program code configured to, when executed by said at least one processor, causes the apparatus or the system to perform at least the following:
generate a voltage by the antenna to represent the signal level indication.

In some embodiments the computer program product comprises computer program code configured to, when executed by said at least one processor, causes the apparatus or the system to perform at least the following:
use a reference voltage as the reference signal; and
compare the generated voltage to the reference voltage.

In some embodiments the computer program product comprises computer program code configured to, when executed by said at least one processor, causes the apparatus or the system to perform at least the following:
determine that the resonance of the antenna fulfills the determined condition if the comparison indicates that the generated voltage is higher than or equal to the reference voltage.

In some embodiments the computer program product comprises computer program code configured to, when executed by said at least one processor, causes the apparatus or the system to perform at least the following:
use a binary signal as the control signal.

In some embodiments of the computer program product the determined condition includes at least one of the following:
a threshold voltage;
a maximum voltage.

According to a fifth example, there is provided an apparatus comprising:
means for receiving an oscillator signal derived from a local oscillator signal;
means for generating a control signal by using the oscillator signal to a resonance tuning circuit configured to be coupled to an antenna circuit;
means for producing a signal level indication on the basis of the resonance of the resonance tuning circuit;
means for comparing the signal level indication with a reference signal; and
means for determining, on the basis of the comparison, whether the resonance of the antenna effected by the generated control signal fulfills a determined condition.

In some embodiments the apparatus further comprises:
means for generating a different value for the control signal and repeating the producing and comparing steps, if the determination indicates that the resonance of the antenna does not fulfill the determined condition.

In some embodiments the apparatus comprises:
means for generating a voltage by the antenna circuit.

In some embodiments the apparatus comprises:
means for using a reference voltage as the reference signal; and
means for comparing the generated voltage to the reference voltage.

In some embodiments the apparatus comprises:
means for determining that the resonance of the antenna fulfills the determined condition if the comparison indicates that the generated voltage is higher than or equal to the reference voltage.

In some embodiments the apparatus comprises:
means for using a capacitance matrix as the resonance tuning circuit.

In some embodiments the apparatus comprises:
means for using the control signal to connect or disconnect capacitors of the capacitance matrix to the antenna.

In some embodiments the apparatus comprises:
means for using a binary signal as the control signal.

In some embodiments of the apparatus the determined condition includes at least one of the following:
a threshold voltage;
a maximum voltage.

According to a fifth example, there is provided an apparatus comprising:
an oscillator signal derived from a local oscillator signal;
a control signal generated by using the oscillator signal to a resonance tuning circuit configured to be coupled to an antenna;
a signal level indication produced on the basis of the resonance of the resonance tuning circuit;
a comparator for comparing the signal level indication with a reference signal; and
a control element configured to determine on the basis of the comparison whether the resonance of the antenna effected by the generated control signal fulfills a determined condition.

In some embodiments the apparatus is further configured to:
generate a different value for the control signal and repeated the producing and comparing steps, if the determination indicates that the resonance of the antenna does not fulfill the determined condition.

In some embodiments of the apparatus the signal level indication comprises a voltage generated by the antenna.

In some embodiments of the apparatus the comparator is configured to:
use a reference voltage as the reference signal; and
compare the generated voltage to the reference voltage.

In some embodiments the apparatus is configured to:
determine that the resonance of the antenna fulfills the determined condition if the comparison indicates that the generated voltage is higher than or equal to the reference voltage.

In some embodiments of the apparatus the resonance tuning circuit comprises a capacitance matrix.

In some embodiments the apparatus is configured to:
use the control signal to connect or disconnect capacitors of the capacitance matrix to the antenna.

In some embodiments of the apparatus the control signal comprises a binary signal.

In some embodiments the apparatus the determined condition includes at least one of the following:
a threshold voltage;
a maximum voltage.

1-50. (canceled)

51. A method comprising:
receiving an oscillator signal derived from a local oscillator signal;
generating, using at least the oscillator signal, a control signal to a resonance tuning circuit configured to be coupled to an antenna;
producing a signal level indication on the basis of the resonance of the resonance tuning circuit;
comparing the signal level indication with a reference signal; and
on the basis of the comparison determining whether the resonance of the antenna effected by the generated control signal fulfills a determined condition.

52. The method according to claim 51 further comprising:
generating a different value for the control signal and repeating the producing and comparing steps, if the determination indicates that the resonance of the antenna does not fulfill the determined condition.

53. The method according to claim 51, wherein producing a signal level indication comprises:
generating a voltage by the antenna.

54. The method according to claim 53, wherein comparing the signal level indication comprises:
using a reference voltage as the reference signal; and
comparing the generated voltage to the reference voltage.

55. The method according to claim 54, wherein the determining comprises:
determining that the resonance of the antenna fulfills the determined condition if the comparison indicates that the generated voltage is higher than or equal to the reference voltage.

56. The method according to claim 51 further comprising:
using a capacitance matrix as the resonance tuning circuit.

57. The method according to claim 56 further comprising:
using the control signal to connect or disconnect capacitors of the capacitance matrix.

58. The method according to claim 51 comprising:
using a binary signal as the control signal.

59. The method according to claim 51, wherein the determined condition includes at least one of the following:
a threshold voltage;
a maximum voltage;
a minimum voltage;
a maximum current;
a minimum current.

60. An apparatus comprising:
a resonance tuning circuit configured to be coupled to an antenna;
a control element comprising an input to receive an oscillator signal derived from a local oscillator signal, the control element configured to produce a control signal for the resonance tuning circuit, using at least the oscillator signal;
a signal level detector to generate a signal level indication on the basis of the resonance of the resonance tuning circuit;
a comparator for comparing the signal level indication with a reference signal; and
the control element further to determine on the basis of the comparison whether the resonance of the antenna effected by the generated control signal fulfills a determined condition.

61. The apparatus according to claim 60 adapted to change the value for the control signal, if the determination indicates that the resonance of the antenna does not fulfill the determined condition.

62. The apparatus according to claim 60 the signal level detector comprising a voltage generating element.

63. The apparatus according to claim 62 comprising a reference voltage adapted to be used as the reference signal, wherein the comparator is configured to compare the generated voltage with the reference voltage.

64. The apparatus according to claim 60 the resonance tuning circuit comprising a capacitance matrix.

65. The apparatus according to claim 64 comprising one or more switches to connect or disconnect capacitors of the capacitance matrix by using the control signal.

66. The apparatus according to claim 60, wherein the control signal is a binary signal.

67. The apparatus according to claim 60, wherein the determined condition includes at least one of the following:
a threshold voltage;
a maximum voltage;
a minimum voltage;
a maximum current;
a minimum current.

68. The apparatus according to claim 60 further comprising the antenna.

69. A computer program product embodied on a non-transitory computer readable medium, comprising computer program code configured to, when executed on at least one processor, cause an apparatus or a system to:
receive an oscillator signal derived from a local oscillator signal;
generate a control signal by using the oscillator signal to a resonance tuning circuit configured to be coupled to an antenna;
produce a signal level indication on the basis of the resonance of the resonance tuning circuit;
compare the signal level indication with a reference signal; and
on the basis of the comparison to determine whether the resonance of the antenna effected by the generated control signal fulfills a determined condition.

70. The computer program product according to claim 69 comprising computer program code configured to, when executed by said at least one processor, causes the apparatus or the system to perform at least the following:
generate a different value for the control signal and repeat the producing and comparing steps, if the determination indicates that the resonance of the antenna does not fulfill the determined condition.
